(19) United States
(12) Patent Application Publication
(10) Pub. No.: US 2013/0299221 A1
(43) Pub. Date: Nov. 14, 2013

(54) SPACE TRANSFORMER FOR PROBE CARD AND METHOD OF MANUFACTURING THE SAME

(71) Applicant: SAMSUNG ELECTRO-MECHANICS CO., LTD., Suwon (KR)

(72) Inventors: Kwang Jae OH, Gyunggi-do (KR); Yoon Hyuck CHOI, Gyunggi-do (KR); Bong Gyun KIM, Gyunggi-do (KR); Joo Yong KIM, Gyunggi-do (KR)

(73) Assignee: SAMSUNG ELECTRO-MECHANICS CO., LTD., Suwon (KR)

(21) Appl. No.: 13/644,910

(22) Filed: Oct. 4, 2012

(30) Foreign Application Priority Data
May 14, 2012 (KR) 10-2012-0050768

(51) Int. Cl. H05K 1/11; H05K 3/10; H05K 1/02

(52) U.S. Cl. 174/258; 174/264; 427/97.3; 427/97.5

(57) ABSTRACT

There is provided a space transformer for a probe card, including: a substrate having a first surface and a second; a plurality of first pads formed on the first surface to be spaced apart from each other and connected to a printed circuit board of a probe card; a plurality of second pads formed on the second surface in positions corresponding to those of the first pads and receiving external electrical signals applied thereto; a plurality of via electrodes penetrating through the substrate and respectively connected to the plurality of first pads and the plurality of second pads formed in the positions corresponding to each other; a ground layer formed to cover the second surface and provided with a plurality of second pad exposure holes; and an insulating layer formed to cover the ground layer and the plurality of second pads.

### CROSS-REFERENCE TO RELATED APPLICATIONS

This application claims the priority of Korean Patent Application No. 10-2012-0050768 filed on May 14, 2012, in the Korean Intellectual Property Office, the disclosure of which is incorporated herein by reference.

### BACKGROUND OF THE INVENTION

1. Field of the Invention

The present invention relates to a space transformer for a probe card and a method of manufacturing the same.

2. Description of the Related Art

Semiconductor devices are manufactured in a fabrication process in which circuit patterns and contact pads are formed on a wafer and an assembly process in which the wafer, on which the circuit patterns and the contact pads are formed, is divided into individual semiconductor device chips.

An electrical die sorting (EDS) process, for determining electrical characteristics of the wafer, is performed by applying electrical signals to the contact pads formed on the wafer during the fabrication process and the assembly process. As a result, the semiconductor devices are sorted into functional devices and defective devices during the EDS process.

In order to sort semiconductor devices in terms of the electrical characteristics thereof, a sorting apparatus including a tester serving to generate sorting signals and to determine sorting results, a performance board, a probe station serving to load and unload the semiconductor wafer, a chuck, a prober, a probe card, and the like, has mainly been used.

A probe card electrically connecting the semiconductor wafer to the tester serves to receive signals generated from the tester through the performance board, transfer the signals to pads on a chip within the wafer, and transfer the signals output from the pads of the chip to the tester, through the performance board.

The probe card may be configured by manufacturing a laminate by stacking a plurality of ceramic green sheets including circuit patterns, electrode pads, via electrodes, and the like, manufacturing a substrate by firing the laminate, and coupling probe pins to the substrate.

As semiconductor device size has been continuously reduced with recent developments in the field of semiconductor integrated technology, demand for a high-precision sorting apparatus for semiconductor devices has increased. Therefore, circuit patterns and contact pads connected to the circuit patterns that are formed on the wafer have been highly integrated in the fabrication process.

That is, as intervals between neighboring contact pads may be very narrow and the contact pads may be very fine in terms of the size thereof, intervals between probe pins mounted on the probe card need to be very narrow and the probe pins need to be finely formed.

In order to minimize distances between the probe pins, a so-called space transformer for compensating for a difference between an interval between terminals on a substrate and an interval between the probe pins has been used between the substrate and the probe pins.

The space transformer may have a plurality of channels applying the electrical signals to the probe, and the number of channels tends to be increased according to the high integration of the wafer chip.

In addition, a space transformer is commonly manufactured after being formally ordered. Since the sizes of ICs to be ordered and intervals or positional information of pads provided therein are variable, the arrangement position of the ICs or the position of the pads on a wafer may be varied. As a result, it may be difficult to anticipatedly manufacture the space transformer ahead of time.

However, a method of manufacturing a space transformer by forming wirings on at least two layers is partially disclosed in the related art, but a pad position is changed according to product, and it is therefore difficult to anticipatedly position vias protruded outwardly of the substrate at a constant interval. Therefore, even in this case, it is difficult to anticipatedly manufacture the space transformer before being ordered.

Patent Document 1 discloses a probe card and a method of manufacturing the same but fails to disclose a structure in which a ground layer is formed on a substrate, which makes it difficult to anticipatedly manufacture a substrate to be commonly applied to a range of probe cards.

### [Related Art Document]

### (Patent Document 1) Korean Patent No. 10-1048497

### SUMMARY OF THE INVENTION

An aspect of the present invention provides a new method of shortening a product delivery date by omitting a period in which a substrate of a space transformer is separately manufactured at the time of manufacturing a probe card by anticipatedly manufacturing the substrate of the space transformer in order that it may be used in probe cards having a variety of configurations.

According to an aspect of the present invention, there is provided a space transformer for a probe card, including: a substrate having a first surface and a second surface opposed to each other; a plurality of first pads formed on the first surface to be spaced apart from each other and connected to a printed circuit board of a probe card; a plurality of second pads formed on the second surface in positions corresponding to those of the first pads and receiving external electrical signals applied thereto; a plurality of via electrodes penetrating through the substrate and respectively connected to the plurality of first pads and the plurality of second pads formed in the positions corresponding to each other; a ground layer formed to cover the second surface and provided with a plurality of second pad exposure holes; and an insulating layer formed to cover the ground layer and the plurality of second pads.

The substrate may have a single layer structure.

The plurality of second pads may have a diameter of 700 μm or more, and a distance between the second pads may be 800 μam or more.

The ground layer may be formed such that the plurality of second pad exposure holes may be larger than the plurality of second pads.

The insulating layer may be formed of a polyimide material.

The insulating layer may further include power wiring patterns formed on a third surface of the insulating layer above the second surface; and at least one or more wiring vias penetrating through the insulating layer and connecting the power wiring patterns to the plurality of second pads.

The insulating layer may further include signal wiring patterns formed on a third surface of the insulating layer above the second surface; and at least one or more wiring vias penetrating through the insulating layer and connecting the signal wiring patterns to the plurality of second pads.

The insulating layer may further include ground wiring patterns formed on a third surface of the insulating layer above the second surface; and at least one or more ground vias penetrating through the insulating layer and connecting the ground wiring patterns to the ground layer.

According to another aspect of the present invention, there is provided a method of manufacturing a space transformer for a probe card, including: preparing a substrate having a first surface and a second surface opposed to each other;

forming a plurality of via holes in the substrate; forming a plurality of via electrodes by filling the via holes with a conductive material; forming a plurality of first pads and a plurality of second pads on the first and second surfaces to be connected with each other by the via electrodes; forming a ground layer on the second surface; forming a plurality of second pad exposure holes in the ground layer so as to expose the plurality of second pads; and forming an insulating layer on the second surface so as to cover the ground layer and the plurality of second pads.

In the preparing of the substrate, the substrate may have a single layer structure.

In the forming of the plurality of via holes, the plurality of via holes may be disposed in the substrate in a matrix array.

In the forming of the plurality of second pad exposure holes, the plurality of second pad exposure holes may be larger than the plurality of second pads so that the ground layer and the plurality of second pads maybe spaced apart from each other.

In the forming of the insulating layer, the insulating layer may be formed by applying and firing a liquid polyimide material on the second surface.

In the forming of the insulating layer, the insulating layer may be formed by compressing a solid polyimide material on the second surface.

The method may further include forming at least one or more wiring via holes in the insulating layer to be connected to at least a portion of the second pads; forming a plurality of wiring vias by filling the wiring via holes with a conductive material; and forming power wiring patterns on a third surface of the insulating layer above the second surface to be connected to the portion of the second pads through the wiring vias.

The method may further include forming at least one or more wiring via holes in the insulating layer to be connected to at least a portion of the second pads; forming a plurality of wiring vias by filling the wiring via holes with a conductive material; and forming signal wiring patterns on a third surface of the insulating layer above the second surface to be connected to the portion of the second pads through the wiring vias.

The method may further include forming at least one or more ground via holes in the insulating layer to be connected to the ground layer; forming a plurality of ground vias by filling the ground via holes with a conductive material; and forming ground wiring patterns on a third surface of the insulating layer above the second surface to be connected to the portion of the second pads through the ground vias.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic configuration diagram of a probe card including a space transformer according to an embodiment of the present invention;

FIG. 2 is a side cross-sectional view schematically showing a portion of a space transformer according to an embodiment of the present invention;

FIG. 3 is a plan view schematically showing a portion of a space transformer in a state in which an insulating layer is removed therefrom according to an embodiment of the present invention;

FIG. 4 is a perspective view schematically showing a space transformer in which an insulating layer is removed therefrom according to an embodiment of the present invention; and

FIG. 5 is a plan view schematically showing a portion of a space transformer and an example of circuit patterns formed on an insulating layer according to an embodiment of the present invention.

### DETAILED DESCRIPTION OF THE EMBODIMENTS

Hereinafter, exemplary embodiments of the present invention will be described with reference to the accompanying drawings.

The invention may, however, be embodied in many different forms and should not be construed as being limited to the embodiments set forth herein.

Rather, these embodiments are provided so that this disclosure will be thorough and complete, and will fully convey the concept of the invention to those skilled in the art.

In the drawings, the shapes and dimensions of elements maybe exaggerated for clarity, and the same reference numerals will be used throughout to designate the same or like elements.

In addition, like or similar reference numerals denote parts performing similar functions and actions throughout the drawings.

In addition, unless explicitly described to the contrary, the word “comprise” and variations such as “comprises” or “comprising” will be understood to imply the inclusion of stated elements but not the exclusion of any other elements.

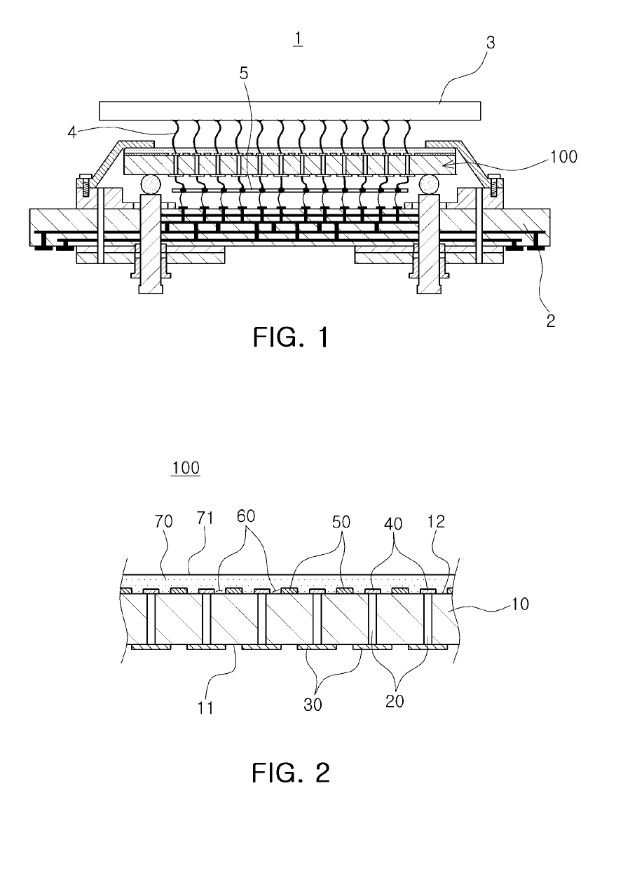

Referring to FIG. 1, a probe card 1 may include a printed circuit board 2, a space transformer 100, and a plurality of probe pins 4 directly contacting a wafer 3 to be sorted.

The printed circuit board 2 may be formed of a circular plate having a top surface and a bottom surface and may be connected to a tester (not shown) for a sorting process.

Probe circuit patterns (not shown) for the sorting process may be formed on the top surface of the printed circuit board 2, grooves (not shown) for suppressing interference between neighboring probe circuit patterns due to current flowing in the probe circuit patterns maybe formed between the neighboring probe circuit patterns, and an interposer 5 may be mounted on the bottom surface of the printed circuit board 2.

The interposer 5 may be disposed in a space provided between the printed circuit board 2 and the space transformer 100 so as to transfer electrical signals through the printed circuit board 2 to the space transformer 100.

One end of the interposer 5 maybe connected to the probe circuit patterns of the printed circuit board 2 and the other end of the interposer 5 may electrically contact first pads to be described below, formed in the space transformer 100.

The probe pins 4 may be formed of a conductive material allowing current to flow therein and may be manufactured using fine thin plate technology applied to a semiconductor manufacture.

Hereinafter, a space transformer according to an embodiment of the present invention will be described.

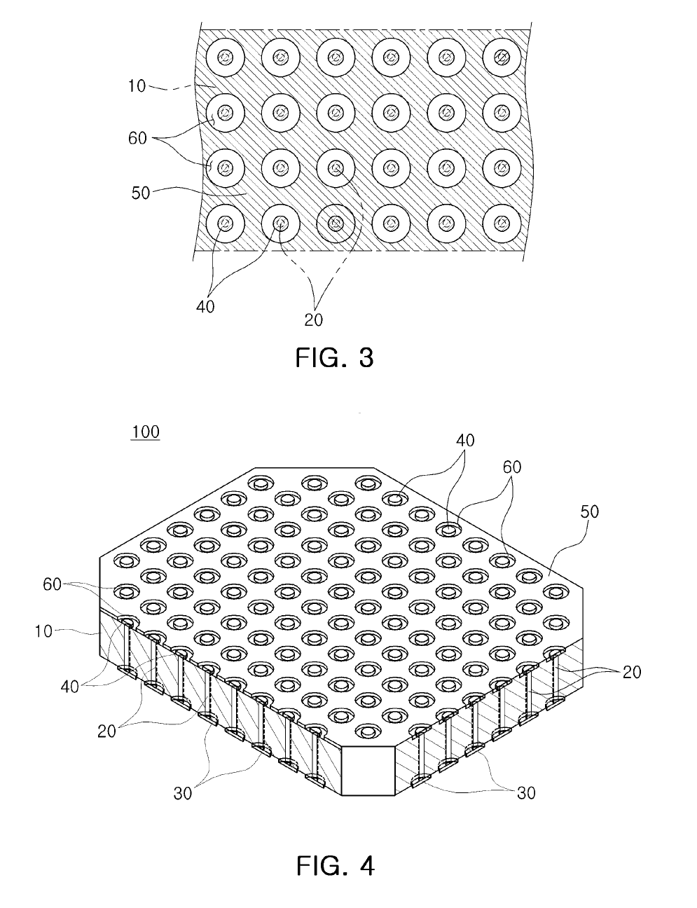

Referring to FIGS. 2 to 4, the space transformer 100 according to the embodiment of the present invention includes a substrate 10 formed of ceramic, glass, silicon, and the like and having a first surface 11 and a second surface 12 opposed to one another.

The substrate 10 may have a single layer structure in which a plurality of via electrodes 20 penetrating therethrough in a thickness direction are spaced apart from each other.

The via electrodes 20 may be formed by a via hole formation process and a via fill process at the time of manufacturing the substrate 10, but a method of forming the via electrodes 20 according to the embodiment of the present invention is not particularly limited.

The first surface 11 of the substrate 10 faces the printed circuit board 2, and a plurality of first pads 30 may be formed in positions corresponding to ends of the individual via electrodes 20 in the first surface 11 and make connection with the interposer 5 of the probe card 1.

That is, the first pad 30 is referred to as a so-called land ground array (LGA) pad allowing the space transformer 100 to be electrically connected through the interposer 5 of the printed circuit board 2.

The second surface 12 of the substrate 10 has a plurality of second pads 40 formed thereon, and the plurality of second pads 40 may be formed in positions corresponding to the respective first pads 30 and the other ends of the respective via electrodes 20 and make connection with the probe pins 4 to thereby receive electrical signals from the wafer 3 applied thereto.

In this configuration, the first and second pads 30 and 40 opposed to one another maybe electrically connected to each other by the via electrodes 20.

A diameter of the second pad 40 may be set to be 700 μm or more when the number of probe pins 4 for testing the wafer 3 is 25,000 or less. In this case, a distance between the second pads 40 may be set to be 800 μm or more.

However, the diameter of the second pad 40 may be set to be 300 μm or more when the number of probe pins 4 for testing the wafer 3 exceeds 25,000. In this case, the distance between the second pads 40 may be set to be 400 μm or more.

The diameter of the second pad 40 and the distance between the second pads 40 are not necessarily evenly applied on a single substrate 10 and therefore, may be increased or reduced in specific positions of the substrate.

In particular, in the case of an edge portion of the substrate 10 or a portion of the substrate 10 to which separate fixtures are attached, the diameter of the second pad 40 and the distance between the second pads 40 may be relatively reduced.

The second surface 12 of the substrate 10 is provided with a ground layer 50 to cover the second surface 12.

The ground layer 50 may be provided with a plurality of second pad exposure holes 60 spaced apart from each other so as to expose the respective second pads 40 to the outside.

In this case, the second pads 40 and the ground layer 50 need to be spaced apart from each other in order to prevent connections therebetween, and accordingly, the second pad exposure holes 60 may be relatively larger than the second pads 40.

The second surface 12 of the substrate 10 is provided with an insulating layer 70 having a predetermined thickness to cover both the second pads 40 and the ground layer 50, and the insulating layer 70 may be formed of polyimide or the like.

Polyimide is generally referred to as a heat-resistant resin having imide coupling (—CO—NH—CO—) with a backbone. Polyimide materials have characteristically high heat resistance, and belong to the group having the highest amounts of heat resistance among engineering plastics. In particular, polyimide materials characteristically do not age, even when they are used for a long period of time at high temperatures.

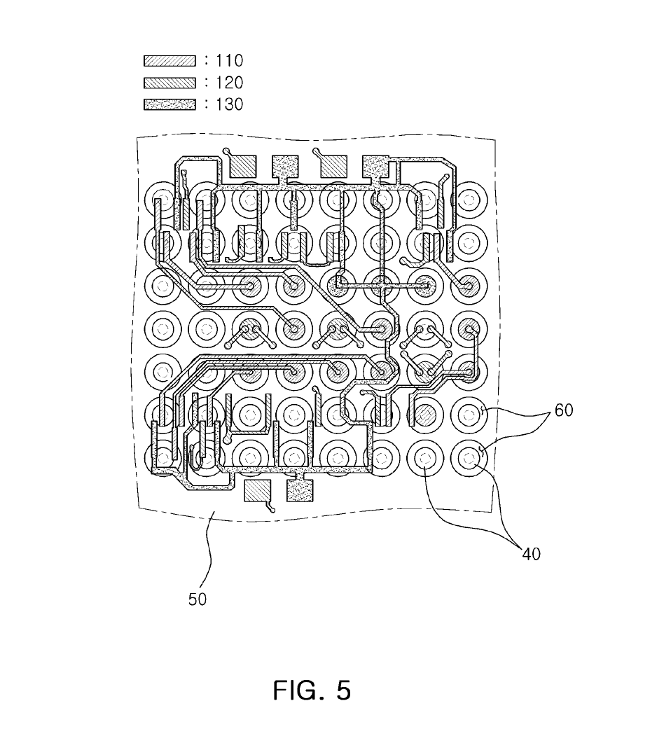

FIG. 5 is a plan view schematically showing a portion of the space transformer and an example of wiring patterns formed on the insulating layer according to the embodiment of the present invention.

FIG. 5 shows a single device under test (DUT). Generally, a single space transformer is provided with about 200 to 1500 DUTs.

Referring to FIG. 5, the insulating layer 70 is provided with a third surface 71 opposed to the second surface 12 of the substrate 10.

The insulating layer 70 has a plurality of ground vias (not shown) penetrating therethrough in a thickness direction with a predetermined interval therebetween and connected to a plurality of wiring vias (not shown) connected to the second pads 40 formed on the second surface 12 of the substrate 10 and the ground layer 50 formed on the second surface 12 of the substrate 10.

In addition, the third surface 71 of the insulating layer 70 may be provided with wiring patterns, such as power wiring patterns 130, signal wiring patterns 120, ground wiring patterns 110, or the like.

That is, the power wiring patterns 130 and the signal wiring patterns 120 may be electrically connected to the second pads through the wiring vias and the ground wiring patterns 110 may be connected to the ground layer 50 through the ground vias .

In this case, conditions in which the power wiring patterns 130 or the signal wiring patterns 120 are individually bound and connected in a single connected pattern may be generated. In the embodiment of the present invention, all the conditions of the wiring patterns can be satisfied even by the substrate having the single layer structure with the help of the wiring pattern design using the insulating layer 70 and the ground layer 50.

The space transformer 100 having the above configuration basically serves to probe the wafer 3 by the probe pins 4 and transfer the probed signals to the printed circuit board 2 of the probe card 1 through the second pads 40.

In the related art, when the probe pins 4 are manufactured using micro electro mechanical systems (MEMS), vias protruded outwardly of the second surface 12 of the substrate 10 should not be formed in positions corresponding to the second pads 40. According to the embodiment of the present invention, the wiring patterns can be designed in various forms using the ground layer 50 and the insulating layer 70 regardless of the limitations.

That is, the related art has a structure in which the pads for connecting the probe pins and several patterns are designed on the second surface of the substrate and the LGA and several patterns are designed on the first surface thereof.

In the space transformer 100 according to the embodiment of the present invention, passive components are mounted on the first surface 11 of the substrate 10 and only the first pads 30 having the existing LGA function are provided thereon, and the first pads 30 may be freely disposed in consideration of the position of the printed circuit board 2.

In addition, the second surface 12 of the substrate 10 is provided with the second pads 40 connected to the via electrodes 20 and the ground layer 50, and the insulating layer 70 is formed on the second pads 40 and the ground layer 50, and the probe pin connecting pads and various wiring patterns are formed on the third surface 71 of the insulating layer 70. Such a structure may reduce components to be designed in a multi-layer circuit structure at the time of manufacturing the related art substrate to a single layer structure that can be easily manufactured.

In addition, only the first and second surfaces 11 and 12 of the substrate 10 and the insulating layer 70 of the space transformer 100 may be anticipatedly manufactured and then, only the wiring pattern and via hole structure of the insulating layer 70 need to be further designed and manufactured at the time of manufacturing the probe card, thereby saving the time consumed to manufacture the space transformer 100 in the process of manufacturing the existing probe card, allowing the delivery date of products to be significantly reduced.

Hereinafter, a method of manufacturing a space transformer for a probe card according to an embodiment of the present invention will be described.

First, the substrate 10 having the first and second surfaces 11 and 12 opposed to one another and formed of a material including ceramic, glass, silicon, or the like is prepared.

The substrate 10 has a single layer structure, thereby further shortening the manufacturing process and time required therefor.

Next, the plurality of via holes are formed in the thickness direction of the substrate 10 at predetermined intervals and then, the individual via holes are filled with a conductive metal such as copper, gold, or the like, by a via fill process, or the like, thereby forming the plurality of via electrodes 20.

The via holes may be formed to be disposed on the substrate 10 in a matrix array, such that a larger number of via electrodes 20 maybe disposed while utilizing the space of the substrate 10 as maximally as possible.

In addition, after the via electrodes 20 are formed, if necessary, a cleaning operation for removing foreign materials such as oil stains, oxides, and the like, from the substrate 10, may be further performed.

Next, the first and second surfaces 11 and 12 of the substrate 10 are respectively provided with the plurality of first and second pads 30 and 40 connected to each other by the via electrodes 20 so as to be opposed to each other.

The first and second pads 30 and 40 may be formed as a seed layer in a dot pattern by forming a seed layer by depositing a conductive metal such as copper, gold, or the like, on the first and second surfaces 11 and 12 of the substrate 10, forming a photoresist layer by applying photoresist to the seed layer in a dot pattern, and etching and removing portions of the seed layer other than portions thereof in which the first or second pads 30 or 40 are formed, according to a mask pattern.

Thereafter, the first or second pads 30 or 40 may be formed by plating a metal material on the seed layer in the dot pattern.

Next, after the ground layer 50 is formed to cover the second surface 12 of the substrate 10, the second pad exposure holes 60 are formed in the ground layer 50 so as to expose the second pads 40 to the outside.

The second pad exposure holes 60 may be larger than the second pads 40 so that the second pads 40 and the ground layer 50 are spaced apart from each other.

Next, the second surface 12 of the substrate 10 is provided with the insulating layer 70 so as to cover the second pads 40 and the ground layer 50, thereby completing the space transformer 100.

The insulating layer 70 may be formed by a method of applying a liquid polyimide material to the second surface 12 and firing the same, a method of compressing a solid polyimide material on the second surface 12, or the like.

In the space transformer 100 for the probe card completed as described above, only the wiring patterns and the vias are further formed on the insulating layer 70 according to the design structure of the probe pins 4 at the time of manufacturing the probe card 1. Hereinafter, a method of adding the wiring patterns and the vias to the space transformer 100 will be described.

A plurality of wiring via holes are formed in the thickness direction of the insulating layer 70 by a laser drilling or thin film process.

Ends of the wiring via holes maybe connected to at least one of the second pads 40 formed on the second surface 12 of the substrate 10.

Next, the plurality of wiring vias are formed by filling respective wiring via holes with a conductive metal by a via fill process, and the like.

Next, wiring patterns such as the power wiring patterns 130, the signal wiring patterns 120, or the like are formed on the third surface 71 of the insulating layer 70 above the second surface 12 of the substrate 10.

When the power wiring patterns 130 or the signal wiring patterns 120 are routed to the third surface 71 of the insulating layer 70, they are bound in a trace or a single surface so as not to be connected to each other and then, may be designed to be connected to the second pads 40 in required positions through the corresponding wiring vias.

Unlike this, the plurality of ground via holes are formed in the thickness direction of the insulating layer 70 by the laser drilling or thin film process.

Ends of the ground via holes may be formed to be connected to the ground layer 50 formed on the second surface 12 of the substrate.

Next, the plurality of ground vias are formed by filling respective ground via holes with a conductive metal by a via fill process, and the like.

Next, the ground wiring patterns 110 are formed on the third surface 71 of the insulating layer 70 above the second surface 12 of the substrate 10.

The ground wiring patterns 110 may be designed to be connected to the ground layer 50 through the ground vias.

In this case, the positions of the ground vias are not limited to specific portions and therefore, positions where the ground vias can easily be designed when being routed may be selected. Therefore, the ground wiring patterns 110 can be bound together while being connected to the ground layer 50 formed on the second surface 12 of the substrate 10.

In addition to this, other wiring patterns or pads for other components may be formed by using a method similar to that of forming the power wiring patterns or the signal wiring patterns as described above.

That is, other wiring patterns or pads are formed on the insulating layer 70 and wiring vias are further formed in required positions of the insulating layer 70, and then, the wiring patterns or the pads are designed to be connected to the required second pads 40 formed on the second surface 12 of the substrate 10 through the additionally formed wiring vias.

Meanwhile, when the routing is not completely finished in the design of the third surface 71 of the insulating layer 70, simple routing maybe undertaken on the first surface 11 of the substrate 10, if necessary.

As set forth above, according to embodiments of the present invention, a substrate of a space transformer is anticipatedly manufactured to meet design requirements regardless of the size of ordered ICs and intervals or positional information of pads, the anticipatedly manufactured space transformer may be used by further designing only wiring patterns according to the structure of probe pins at the time of manufacturing a probe card, thereby omitting a period in which the substrate of the space transformer is separately manufactured at the time of manufacturing the probe card, resulting in a reduction in manufacturing time and delivery date of products.

While the present invention has been shown and described in connection with the embodiments, it will be apparent to those skilled in the art that modifications and variations can be made without departing from the spirit and scope of the invention as defined by the appended claims.

What is claimed is:

1. A space transformer for a probe card, comprising:
a substrate having a first surface and a second surface opposed to each other;
a plurality of first pads formed on the first surface to be spaced apart from each other and connected to a printed circuit board of a probe card;
a plurality of second pads formed on the second surface in positions corresponding to those of the first pads and receiving external electrical signals applied thereto;
a plurality of via electrodes penetrating through the substrate and respectively connected to the plurality of first pads and the plurality of second pads formed in the positions corresponding to each other;
a ground layer formed to cover the second surface and provided with a plurality of second pad exposure holes; and
an insulating layer formed to cover the ground layer and the plurality of second pads.

2. The space transformer for a probe card of claim 1, wherein the substrate has a single layer structure.

3. The space transformer for a probe card of claim 1, wherein the plurality of second pads have a diameter of 700 μm or more, and
a distance between the second pads is 800 μm or more.

4. The space transformer for a probe card of claim 1, wherein the ground layer is formed such that the plurality of second pad exposure holes are larger than the plurality of second pads.

5. The space transformer for a probe card of claim 1, wherein the insulating layer is formed of a polyimide material.

6. The space transformer for a probe card of claim 1, wherein the insulating layer further includes:
power wiring patterns formed on a third surface of the insulating layer above the second surface; and
at least one or more wiring vias penetrating through the insulating layer and connecting the power wiring patterns to the plurality of second pads.

7. The space transformer for a probe card of claim 1, wherein the insulating layer further includes:
signal wiring patterns formed on a third surface of the insulating layer above the second surface; and
at least one or more wiring vias penetrating through the insulating layer and connecting the signal wiring patterns to the plurality of second pads.

8. The space transformer for a probe card of claim 1, wherein the insulating layer further includes:
ground wiring patterns formed on a third surface of the insulating layer above the second surface; and
at least one or more ground vias penetrating through the insulating layer and connecting the ground wiring patterns to the ground layer.

9. A method of manufacturing a space transformer for a probe card, the method comprising:
preparing a substrate having a first surface and a second surface opposed to each other;
forming a plurality of via holes in the substrate;
forming a plurality of via electrodes by filling the via holes with a conductive material;
forming a plurality of first pads and a plurality of second pads on the first and second surfaces to be connected with each other by the via electrodes;
forming a ground layer on the second surface;
forming a plurality of second pad exposure holes in the ground layer so as to expose the plurality of second pads; and
forming an insulating layer on the second surface so as to cover the ground layer and the plurality of second pads.

10. The method of claim 9, wherein, in the preparing of the substrate, the substrate has a single layer structure.

11. The method of claim 9, wherein, in the forming of the plurality of via holes, the plurality of via holes are disposed in the substrate in a matrix array.

12. The method of claim 9, wherein, in the forming of the plurality of second pad exposure holes, the plurality of second pad exposure holes are larger than the plurality of second pads so that the ground layer and the plurality of second pads are spaced apart from each other.

13. The method of claim 9, wherein, in the forming of the insulating layer, the insulating layer is formed by applying and firing a liquid polyimide material on the second surface.

14. The method of claim 9, wherein, in the forming of the insulating layer, the insulating layer is formed by compressing a solid polyimide material on the second surface.

15. The method of claim 9, further comprising:
forming at least one or more wiring via holes in the insulating layer to be connected to at least a portion of the second pads;
forming a plurality of wiring vias by filling the wiring via holes with a conductive material; and
forming power wiring patterns on a third surface of the insulating layer above the second surface to be connected to the portion of the second pads through the wiring vias.

16. The method of claim 9, further comprising:
forming at least one or more wiring via holes in the insulating layer to be connected to at least a portion of the second pads;
forming a plurality of wiring vias by filling the wiring via holes with a conductive material; and
forming signal wiring patterns on a third surface of the insulating layer above the second surface to be connected to the portion of the second pads through the wiring vias.

17. The method of claim 9, further comprising:
forming at least one or more ground via holes in the insulating layer to be connected to the ground layer;
forming a plurality of ground vias by filling the ground via holes with a conductive material; and
forming ground wiring patterns on a third surface of the insulating layer above the second surface to be connected to the portion of the second pads through the ground vias.
